(19) United States
(12) Patent Application Publication
(10) Pub. No.: US 2011/0308942 A1
(43) Pub. Date: Dec. 22, 2011

(54) MICROELECTRODE ARRAY SENSOR FOR DETECTION OF HEAVY METALS IN AQUEOUS SOLUTIONS

(75) Inventors: Erjia Liu, Singapore (SG); Wenguang Ma, Singapore (SG); Guocheng Yang, Singapore (SG); Aiping Liu, Singapore (SG); Nay Win Khun, Singapore (SG); Zhaomeng Wang, Singapore (SG)

(73) Assignee: Nanyang Technological University, Singapore (SG)

(21) Appl. No.: 12/842,857

(22) Filed: Jul. 23, 2010

(30) Foreign Application Priority Data
Jun. 16, 2010 (SG) 201004224-0

(51) Int. Cl. G01N 27/30; G03F 7/20

(52) U.S. Cl. 204/400; 430/319

(57) ABSTRACT

In a first aspect, the present invention is directed to a microelectrode array for detecting heavy metals in an aqueous solution. The microelectrode array can comprise a layer of a doped carbon film and a patterning layer arranged on the doped carbon film for defining multiple microelectrodes in the doped carbon film to form the microelectrode array. The size, and shape, and arrangement of each of the multiple microelectrodes can be defined by the size, and shape, and arrangement of each of the openings in the patterning layer which expose the underlying doped carbon film. Furthermore, the ratio of the maximal width of a microelectrode relative to the shortest distance between the neighboring microelectrodes (center to center) in the microelectrode array is between about 1:1.2 and about 1:6. The present invention is also directed to an apparatus using the microelectrode array and methods of manufacturing the same.

### CROSS-REFERENCE TO RELATED APPLICATION

This application claims the benefit of priority of SG application No. 201004224-0, filed Jun. 16, 2010, the content of it being hereby incorporated by reference in its entirety for all purposes.

### FIELD OF THE INVENTION

The present invention is directed to the field of electrochemistry. In particular the present invention is directed to the field of electrochemical detection of heavy metals.

### BACKGROUND OF THE INVENTION

Considerable attention has been given to the search for new solid electrode materials for use as sensor materials for the determination of heavy metals (such as Cu, Cd, Pb, Zn) in waste water and biofluid systems. The search concentrated on solid electrode materials with wide potential window, fast response and high activity for electroanalysis applications because traditional hanging mercury drop electrodes, noble metal electrodes, graphite and glassy carbon electrodes can either cause a serious environmental impact or represent a limited sensitivity in terms of the surface oxidation and reduction of the electrodes. Much of this effort has been involved in boron doped diamond (BDD) electrodes within the past decade with respect to their advantageous properties.

It is therefore an object of the present invention to provide alternative materials and systems which can be used for the determination of heavy metals (such as Cu, Cd, Pb, or Zn) in waste water reclamation plants and other fluid systems.

### SUMMARY OF THE INVENTION

In a first aspect, the present invention is directed to a microelectrode array for detecting heavy metals in an aqueous solution. The microelectrode array can comprise a layer of a doped carbon film and a patterning layer arranged on the doped carbon film for defining multiple microelectrodes in the doped carbon film to form the microelectrode array. The dimensions, such as size, and shape, and arrangement of each of the multiple microelectrodes can be defined by the dimensions, such as size, and shape, and arrangement of each of the openings in the patterning layer which expose the underlying doped carbon film. Furthermore, the ratio of the maximal width of a microelectrode relative to the shortest distance between the neighboring microelectrodes (center to center) in the microelectrode array is between about 1:1.2 and about 1:6.

In another aspect, the present invention refers to an apparatus for detecting heavy metals in an aqueous solution. The apparatus can comprise a measuring cell for an aqueous test sample and a working electrode comprising the microelectrode array of the present invention. The working electrode can be arranged to expose the microelectrode array to the aqueous test sample in the measuring cell.

In still another aspect, the present invention is directed to a water treatment plant comprising an apparatus of the present invention.

In still another aspect, the present invention is directed to a method of manufacturing a microelectrode array of the present invention. The method can comprise coating a patterning layer on a doped carbon film. It can further comprise baking the patterning layer to densify the patterning layer and covering it with a masking layer and exposing the baked and masked patterning layer to UV radiation. It can further comprise performing a post-exposure baking and performing a development process to remove portions of the baked and masked patterning layer thereby exposing areas of the doped carbon film which areas form microelectrodes of the microelectrode array.

### BRIEF DESCRIPTION OF THE DRAWINGS

The invention will be better understood with reference to the detailed description when considered in conjunction with the non-limiting examples and the accompanying drawings, in which:

FIG. 1 shows a schematic view of an embodiment of an apparatus of the invention. The apparatus or electrochemical cell is made of Teflon® with the container 1 of 52.75 mL in volume. The two openings or holes 2 and 3 on both sides of the container are 4 mm and 7.6 mm in diameters, respectively, which allows two different sizes of working electrodes in operation at the same time. The two working electrodes 4 and 5 are close to the holes on both sides of the container with two O-rings 6 and 7 sealing the working electrodes and avoiding the leakage of liquid in the cell. The two clamped plates 8 and 9 are pressed to firmly hold the two working electrodes 4 and 5 by means of four metal snap fasteners 14 that also consolidate the container and clamped plates. The metal wires 10 and 11 adhered to the electrode 4 and 5 surfaces are connected to the control unit. The Teflon® cap 12 is used to hold reference and auxiliary electrodes. Some liquid can be injected into the container 1 through one of the three holes in the cap 12. The holder 13 made of Teflon® can be used to fix a tube to inject gas. FIG. 1 illustrates that the working electrodes 4 and 5 can be used independently from each other, i.e. the apparatus works also with only one working electrode. The exposed areas of the working electrodes 4 and 5 are controlled by those of the holes 2 and 3.

FIG. 2 shows a cross-sectional view of a container 1.

FIG. 3 shows a cross-sectional view of a clamped plate 8.

FIG. 4 shows a cross-sectional view of a holder 13.

FIG. 5 shows a cross-sectional view of a cap 12.

FIG. 6 schematically depicts a cross-sectional view of an embodiment of a microelectrode array. The substrate 15 is conductive silicon wafer, preferable p-type (100) silicon wafer. The diamond like carbon (DLC) film 16 is a doped DLC film which can be prepared by filtered cathodic vacuum arc or by magnetron sputtering. A possible dopant is nitrogen. The electrical resistivity of the DLC is less than 10⁴ Ohm·cm. The patterning layer or surface layer 17 on the DLC 16 is a SU-8 photoresist layer that is treated by soft baking, exposure to UV irradiation, post exposure baking and development consecutively. The SU-8 photoresist layer 17 can be adhered to the DLC 16 to avoid the solution immersion and contacting with the DLC layer 16. The exposed microelectrodes 18 are coplanar and separated by the photoresist patterned layer 17. The microelectrodes 18 are microdiscs which can have a diameter of between about 3 μm and about 100 μm and a shortest distance of about 3.6 μm to about 600 μm between the neighboring microdiscs (center to center). The metal wire 19 is adhered to the surface of the DLC 16, which is connected to the outer circuit at the other end. Alternatively, the substrate 15 can also be Si/SiO₂ wafer and the DLC 16 is deposited on the surface of the insulative SiO₂ layer.

FIG. 7 shows an exemplary flowchart of preparing DLC-based microelectrodes by photolithography.

FIG. 8 shows an optical micrograph of nitrogen doped DLC single microelectrode which was used as control to compare the performance of the microelectrode array of the present invention with the performance of a single microelectrode as the one shown in FIG. 8.

FIG. 9A shows an optical micrograph of a nitrogen doped DLC microelectrode array; FIG. 9B schematically shows a microelectrode array arranged in square grids; FIG. 9C schematically shows a microelectrode array patterned in concentric circular grids; and FIG. 9D schematically shows a microelectrode array patterned in equilateral triangular grids. All the three schematic arrays shown in FIG. 9B-D have the same diameter of 3 mm, and same size of individual microelectrodes of 100 μm in diameter, and same shortest spacing between the neighboring microelectrodes (center to center) of 250 μm.

FIG. 10 shows a cyclic voltammogram (CV) and a differential pulse voltammogram (DPV) of a nitrogen doped DLC microelectrode array comprising microelectrodes having a diameter of 100 μm measured in a 0.1 M NaAc+HAc solution (pH 4.1). The potentials for hydrogen and oxygen evolutions are about −0.6 and +1.8 V respectively vs. an Ag/AgCl electrode in the CV curve and about −1.2 and +1.7 V respectively in the DPV curve. The background current is about 0.2 μA. The wide potential window and low background current indicate the favorable capability of a microelectrode array using doped carbon microelectrode layers, such as nitrogen doped DLC microelectrode layers, for the detection, for example of trace heavy metals.

FIG. 11 shows cyclic voltammograms obtained with a nitrogen doped DLC single microelectrode with a diameter of 100 μm in a solution containing 0.1 M KCl and 5 mM K₃Fe(CN)₆ at different scan rates. The response current increases with increasing scan rate. The results indicate the electrocatalytic activity of the single microelectrode for the Fe(CN)₆⁴⁻/Fe(CN)₆³⁻ redox reactions.

FIG. 12 illustrates the stripping current responses obtained with a nitrogen doped DLC microelectrode array in a 0.1 M NaAc+HAc solution (pH 4.1) containing Pb ions. The diameter of a circular microelectrode in the array is 100 μm and the shortest spacing between the neighboring microelectrodes (center to center) is 130 μm. The stripping peak position of Pb is at about −0.55 V and the peak position shifts positively and the peak intensity increases with the increasing concentration of Pb (0.7˜1.3×10⁻⁶ M) on the DLC microelectrode array. It can be deduced that the nitrogen doped DLC microelectrode arrays can detect the Pb ions in the aqueous solutions.

FIG. 13 shows the stripping current responses obtained with a nitrogen doped DLC microelectrode array in a 0.1 M NaAc+HAc solution (pH 4.1) containing Pb and Cu ions. The diameter of a circular microelectrode in the array is 100 μm and the shortest spacing between the neighboring microelectrodes (center to center) is 130 μm. The stripping peak position of Pb is at about −0.55 V and that of copper is at about +0.02 V. The both peak positions shift positively and both peak intensities increase with the increasing concentrations of Pb and Cu from 3 to 8×10⁻⁷ M on the DLC microelectrode array. The results indicate that the nitrogen doped DLC microelectrode arrays can simultaneously detect the Pb and Cu ions in the aqueous solutions.

FIG. 14 A illustrates current responses of different nitrogen-doped DLC thin film microelectrodes in an array of microelectrodes, wherein the entire microelectrode array has a diameter of 3 mm in 0.1 M NaAc+HAc solutions (pH 6.0) including Pb and Cu ions. The corresponding calibration plots are also shown (FIGS. 14 B and C).

FIG. 15 A illustrates stripping current responses of different nitrogen-doped DLC microelectrode arrays with a diameter of 100 μm for each microelectrode and the shortest spacing between the neighboring microelectrodes (center to center) of 250 μm in 0.1 M NaAc+HAc solutions (pH 6.0) including Pb and Cu ions. The corresponding calibration plots are also shown (FIGS. 15 B and C).

FIG. 16 A illustrates stripping current responses of different nitrogen-doped DLC electrode arrays with the individual electrodes of different diameters from 3 μm up to 300 μm in 0.1 M NaAc+HAc solutions (pH 6.0) including Pb and Cu ions. The stripping curves measured from a single macroelectrode of 3500 μm in diameter are also included for comparison. The corresponding calibration plots are also shown (FIGS. 16 B and C).

FIG. 17 illustrates stripping current responses of nitrogen-doped DLC microelectrode arrays with a diameter of 100 μm for each microelectrode and the shortest spacing between the neighboring microelectrodes (center to center) of 250 μm and different thicknesses of photoresist layers on them in 0.1 M NaAc+HAc solutions (pH 6.0) including Pb and Cu ions.

### DETAILED DESCRIPTION OF THE PRESENT INVENTION

In a first aspect the present invention refers to a microelectrode array for detecting heavy metals in an aqueous solution. The microelectrode array can comprise a layer of a doped carbon film and a patterning layer arranged on the doped carbon film for defining multiple microelectrodes in the doped carbon film to form the microelectrode array. The dimension, such as size, and shape, and arrangement of each of the multiple microelectrodes can be defined by the dimensions, such as size, and shape, and arrangement of each of the openings in the patterning layer which expose the underlying doped carbon film. Furthermore, the ratio of the maximal width of a microelectrode relative to the shortest distance between the neighboring microelectrodes (center to center) in the microelectrode array is between about 1:1.2 and about 1:6.

In general, microelectrodes (maximal width of a microelectrode ≦100 μm have significant advantages over conventional macroelectrodes (width of a macroelectrode >100 μm) due to their enhanced instantaneous and spatial resolutions, decreased effect of solution resistance and increased current density and signal-to-noise (S/N) ratio. However, a relatively low current obtained on a single microelectrode restricts or inhibits its use in the on site sensing. Therefore, arrays of microelectrodes have been designed and prototyped. In these systems, the multiple microelectrodes are placed electrically in parallel to each other so that their diffusional fields do not overlap at suitable scan rates. The signals generated from each microelectrode in an array are progressive and greatly enhanced when compared to a single microelectrode or macroelectrodes.

Microelectrode arrays described herein are well suited for application in extremely aggressive environments such as waste water and biofluid. In particular, the microelectrode arrays are well suited for operation in acid (pH 1 to 6), alkaline (pH 8 to 12) and neutral (pH 7) environments and in the presence of organic solvents.

Microelectrode arrays described herein provide significantly higher current response and S/N ratio than conventional macroelectrodes. Furthermore, microelectrode arrays described herein provide higher current response and S/N ratio than single microelectrodes, such as single diamond like carbon microelectrodes.

Also, microelectrode arrays described herein are inexpensive and can be grown on virtually any substrate having a smooth surface at low temperature or room temperature, which exhibits important advantages over the difficult-to-nucleate, high-temperature grown polycrystalline boron doped diamond (BDD) electrodes.

Microelectrode arrays described herein provide a wide range of operation potentials for monitoring redox reactions in electrolytic solutions. Such microelectrode arrays have a potential to replace toxic mercury used most frequently for determination of trace heavy metals in water and biofluid systems by anodic stripping voltammetry (ASV). An apparatus using a microelectrode array described herein as the working electrode is cabinet, portable and convenient, which is suitable for the on site detection of trace heavy metals in water.

The ratio of the maximal width of a microelectrode relative to the shortest distance between the neighboring microelectrodes (center to center) in the microelectrode array is between about 1:1.2 and about 1:6 to avoid an overlap of diffusional fields between the neighboring microelectrodes in the array during measurement. A diffusional field means an area for current permeation surrounding an electrode. A diffusional field is usually larger than the area of an electrode. If a spacing between two neighboring microelectrodes is small, their diffusional fields could overlap, resulting in the degradation of the performance of the microelectrodes. In one embodiment, the ratio of the maximal width of a microelectrode relative to the shortest distance between the neighboring microelectrodes (center to center) in the microelectrode array is between about 1:1.2 and about 1:3; or about 1:1.2 and about 1:2.5; or about 1:1.3 to about 1:2.5, or 1:1.2 to about 1:1.5.

Such microelectrode arrays developed by the inventors allow detection of heavy metal ions in an aqueous solution at a concentration as low as 3×10⁻⁷ M.

In general, an electrode is understood as a solid electric conductor through which an electric current enters or leaves an electrolytic cell or other medium. A microelectrode is understood as an electrode with a maximal width equal or below 100 μm while a macroelectrode is understood herein as an electrode with a maximal width more than 100 μm. A single macroelectrode or microelectrode is different from an array of macroelectrodes or microelectrodes, respectively. For example, an array of microelectrodes comprises multiple single microelectrodes. The density of a microelectrode array described herein is dependent on the size, and shape, and arrangement of single microelectrodes in it. If the diameter of single microelectrodes in an array is 100 μm, the range of density is from about 200 microelectrodes/cm² to about 4.5×10³ microelectrodes/cm². However, if the diameter of single microelectrodes in an array is as small as 3 μm, the range of density is from about 2×10⁵ microelectrodes/cm² to about 4.9×10⁶ microelectrodes/cm².

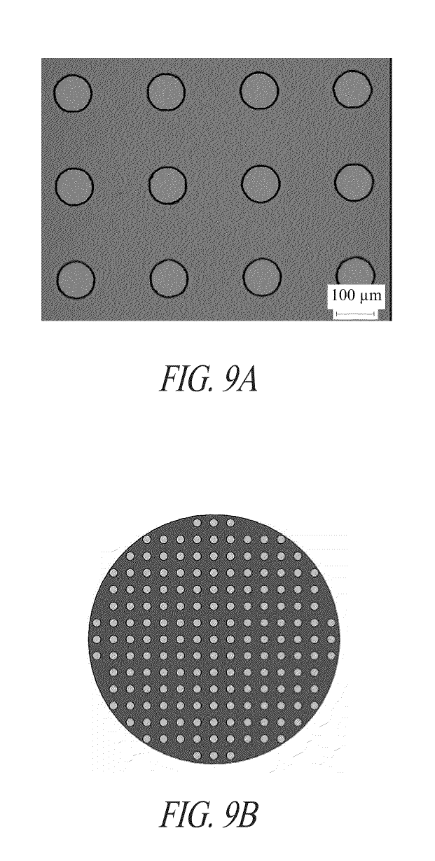

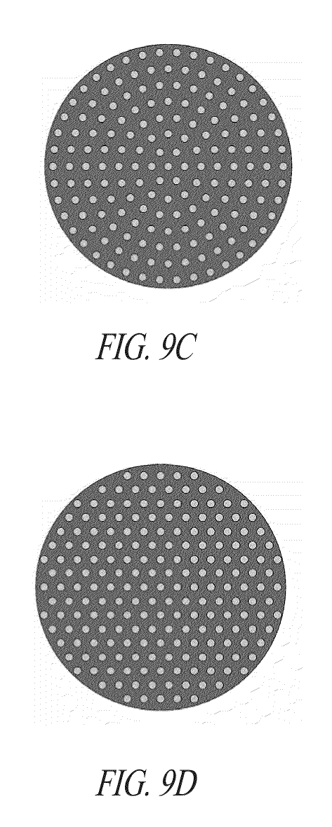

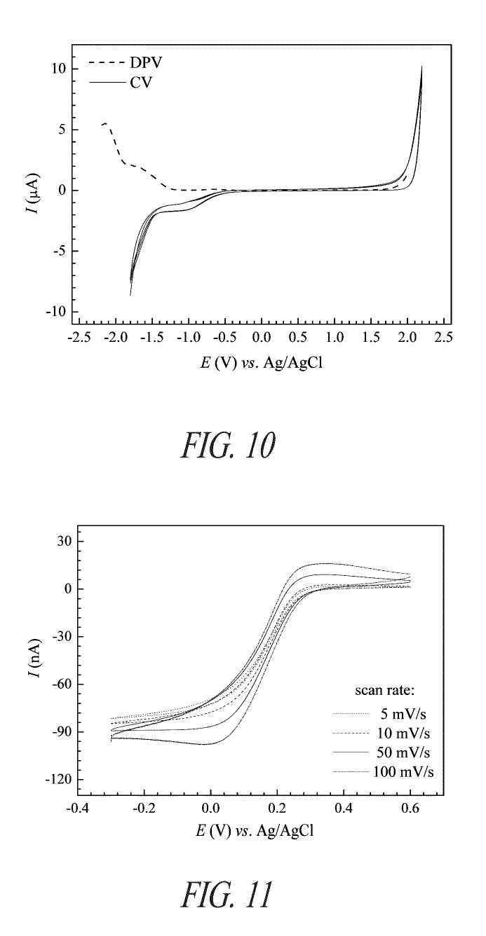

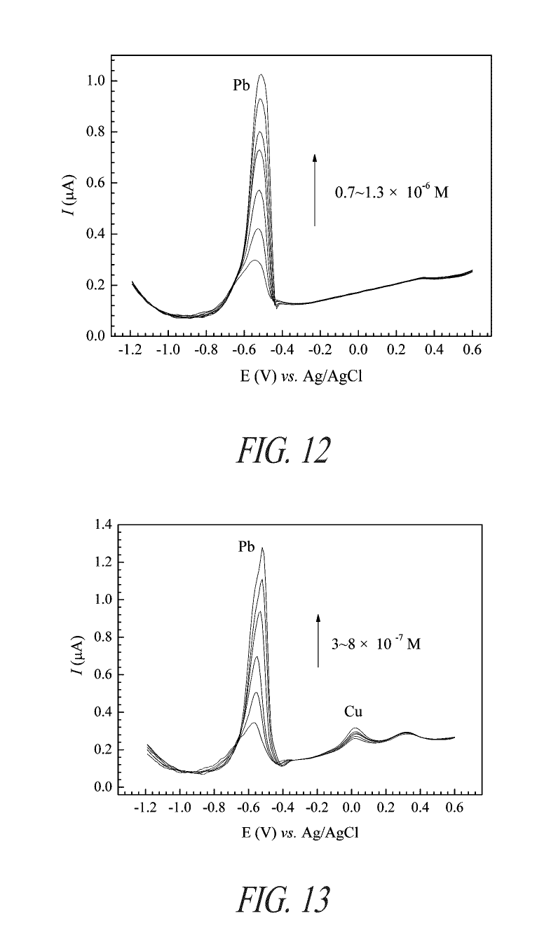

An array of microelectrodes can comprise microelectrodes in any arrangement. As illustrated for example in FIG. 9, microelectrodes in an array of microelectrodes can be arranged in square grids, or circular grids or triangular grids.

In such a microelectrode array an electrical circuit in electrical communication with each of the microelectrodes of the array converts electrical signals obtained from the microelectrodes which are associated with a characteristic being monitored.

A microelectrode array described herein can for example be used for stripping voltammetry. “Voltammetry” refers to methods in which the current in an electrochemical system is measured as the voltage of the system is changed. “Stripping voltammetry” is a specific application of voltammetry. Stripping voltammetry is a sensitive electroanalytical technique for the determination of trace amounts of heavy metals in solution. To summarize the measuring principle of this technique, heavy metal ions in an aqueous test sample are first reduced to metallic form and concentrated at the electrode surface. After concentration, they are re-oxidized into solution (“stripped”) from the electrode (i.e. re-oxidized into their soluble form). The pre-concentration step permits analysis of very low levels of metal ions. The method is used to analyze trace levels of heavy metals in a variety of environmental samples. Quantitation is achieved via known methods, such as standard additions.

In more detail, in stripping voltammetry measurements, at first heavy metal ions comprised in an aqueous test sample are reduced to metals and deposited onto an electrode which is held at a suitable potential. A reference electrode is used to monitor the potential of the working electrode. To complete the electrochemical cell an auxiliary electrode can be used. The potentials of the working and auxiliary electrodes are adjusted with respect to the reference electrode to maintain the desired potential at the working electrode. The aqueous test sample can be agitated during the deposition of the heavy metal at the surface of the working electrode to maximize the amount of metal deposited. Second, agitation is stopped so that the aqueous test sample will become quiet. Third, the metal deposits are stripped from the electrode by scanning the potential to re-oxidize the metal deposits. The observed current during the stripping step can be related to the amount of the metal in the solution.

Heavy metals which can be detected with this method also include some toxic metals. Such heavy metals include, but are not limited to mercury (Hg), arsenic (As), chromium (Cr), copper (Cu), cadmium (Cd), lead (Pb), zinc (Zn), manganese (Mn), and iron (Fe). The microelectrode array described herein allows detection of more than one heavy metal at the same time as demonstrated in the experimental section. Two, three or four heavy metals are usually suitable for a simultaneous detection.

The stripping step may consist of a positive or a negative potential scan, creating either an anodic or cathodic current, respectively. Hence, Anodic Stripping Voltammetry (ASV) and Cathodic Stripping Voltammetry (CSV) are two specific stripping techniques. In addition to varying the direction of the scan, the manner in which the potential is scanned may also differ. The simplest technique is Linear Sweep Voltammetry (LSV) where the potential is scanned linearly as a function of time. Another commonly used technique is Differential Pulse Voltammetry (DPV), which can have a lower detection limit than LSV. This is due to its pulsed waveform which measures the current in pulses by taking two measurements and recording the difference as the potential is increased. This can further help to reduce the background current. The waveforms from each pulse superimpose upon one another to form a staircase waveform since the pulse amplitude is constant while the potential increases in small increments. One more commonly used technique is square wave voltammetry (SWV), which is a further development of DPV. With DPV a pulsed potential is scanned through a defined range (na, na+A), while with SWV a pulsed potential is scanned within (na−A, na+A), where A is the pulse amplitude, a is the step increase and n is the number of pulses. Similar to DPV, SWV has excellent sensitivity and perfect rejection of background current because the recorded current is the difference between the average currents from the forward and reverse pulses. The microelectrode array described herein can be used in any of these stripping voltammetry techniques.

In the microelectrode array described herein a doped carbon film is used as electrode. Carbon films for this use are characterized by a low electrical resistivity, low dielectric constant, chemical inertness, low double layer capacitance, large potential window, low background current, excellent mechanics and low friction and wear. The carbon films used herein can be a diamond like carbon (DLC) material.

Carbon usually exists in several forms; graphite, diamond, and the new forms of carbon nanotube and fullerene. All four of these forms are crystalline in structure but have varying properties based on the bonding order of the carbon atoms. Diamond-like carbon (DLC) is a metastable form of amorphous carbon containing both sp² and sp³ bonded carbon. As such, DLC has both diamond-like and graphitic properties, hence the name diamond-like carbon (DLC). As used herein, “diamond-like carbon (DLC)” refers to a carbonaceous material having carbon atoms as the majority element, with a substantial amount of such carbon atoms bonded in distorted tetrahedral coordination. Diamond-like carbon (DLC) can either comprise solely carbon or be doped (slightly or substantially) with one or more other elements, such as any one of N, H, Al, Ni, Ti, Pt, Ru or mixtures thereof. In the doped DLC, the amount of carbon is still dominating, wherein the carbon content of doped DLC can be between about 60 at. % to about 99.5 at. %. In another embodiment, the amount of carbon in diamond like carbon can be at least 70% or 80% or 90% or 95% or 99% or 99.5%.

A diamond-like carbon (DLC) film is produced when carbon is deposited under energetic conditions. Carbon is then strongly bonded in all directions as in diamond, but as an amorphous structure, while in contrast graphite is strongly bonded in a plane, but weakly between planes.

Known methods of producing the strongly bonded structure of DLC is for example by deposition from a RF plasma, sustained in hydrocarbon gases, onto substrates negatively biased (plasma assisted chemical vapour deposition or PACVD). Another method is sputtering deposition of carbon with or without bombardment by an intense flux of ions (physical vapour deposition or PVD), such as cathodic arc deposition (Arc-PVD); or magnetron sputtering, such as DC magnetron sputtering.

In filtered cathodic vacuum arc (FCVA) deposition, an arc is initiated by touching the graphite cathode with a small carbon striker electrode and quickly withdrawing the striker in a high vacuum chamber. This produces energetic plasma with a high ion density. The cathode spot is formed by an explosive emission process. This creates particulates as well as the desired plasma. The particulates can be filtered by passing the plasma along a toroidal magnetic filter duct. The plasma beam is condensed onto a substrate to produce DLC films with a high content of sp^{a} bonds. In contrast to diamond, no external heating is applied; therefore temperature sensitive substrate materials such as plastics and collagen can be coated as well as a wide range of metals and ceramics.

The carbon film used herein, such as a diamond like carbon (DLC) film, is doped with one or more dopants. Dopants can increase conduction by reducing ohmic resistivity in the carbon films. A suitable dopant can be nitrogen which can increase conductivity of such films without obvious change of the microstructure of films. Platinum and ruthenium can also be dopants which can increase the conductivity of DLC films with obvious metal-induced graphitization of the films. For example, in one embodiment the content of Pt is about 2.2-4.2 at. % and that of Ru is about 2.4 to 5.1 at. % in the Pt/Ru doped DLC films. Further dopants can include, but are not limited to aluminium which can be used to increase the conductivity and reduce the residual stress of such films; or nickel which can increase the conductivity and electrochemical activity of such films, especially for glucose oxidation. In one embodiment, nitrogen has been used as dopant. Suitable combinations of those dopants allow adapting the characteristics of the microelectrode arrays to specific applications. For example, a DLC film can be doped with nitrogen and nickel, or with nitrogen and aluminium, or with nitrogen and a mixture of platinum and ruthenium, or with nitrogen and titanium, or with nitrogen, aluminium and a mixture of platinum and ruthenium.

In one embodiment, the dopant, such as nitrogen can be comprised in the carbon film in a total amount of at least 0.5 atomic percent (at. %). In another embodiment, the amount of dopant, such as nitrogen in the carbon film is between about 0.5 at. % to about 3 at. %. In another example, the amount of dopant in the carbon film is about 0.5 at. % or about 1 at. %. Atomic percent (at. %) describes the percentage of one kind of atom relative to the total number of atoms in a material. In one embodiment, nitrogen content in carbon film, such as DLC film, is lower than 3 at. % when nitrogen flow rate does not exceed 10 sccm (1.67×10⁻⁷ m³/s) during manufacture. The ability to detect heavy metals for such electrodes was tested to be higher than for doped carbon films having higher nitrogen content in the films. Thus, in one embodiment flow rate for dopants during manufacture is equal or below 10 sccm (1.67×10⁻⁷ m³/s). Control of dopant flow rate in this manner allows obtaining electrochemically active microelectrodes without obvious structural changes of the microstructure.

Use of these dopants can result in a resistivity of the doped carbon films of the microelectrodes in the microelectrode arrays of below 10⁴ Ohm·cm. A higher dopant content can also increase the adhesion strength of doped carbon films. A higher dopant content can reduce the residual stress in doped carbon films. A higher adhesion strength of the doped carbon films can significantly lessen the delamination tendency of the films so as to improve the electrochemical performance of the films, such as sensitivity, repeatability, stability and robustness. The thickness of the doped carbon film can be below 1 μm or below 500 nm. The thickness of DLC films can affect the conductivity of the films. If a DLC film is too thin, it will be easily broken-down when a high potential is applied to it during electrochemical analysis. However, if a DLC film is too thick, the resistivity of the film increases. Thus, in one embodiment thickness of DLC films can be between about 50 nm and about 300 nm.

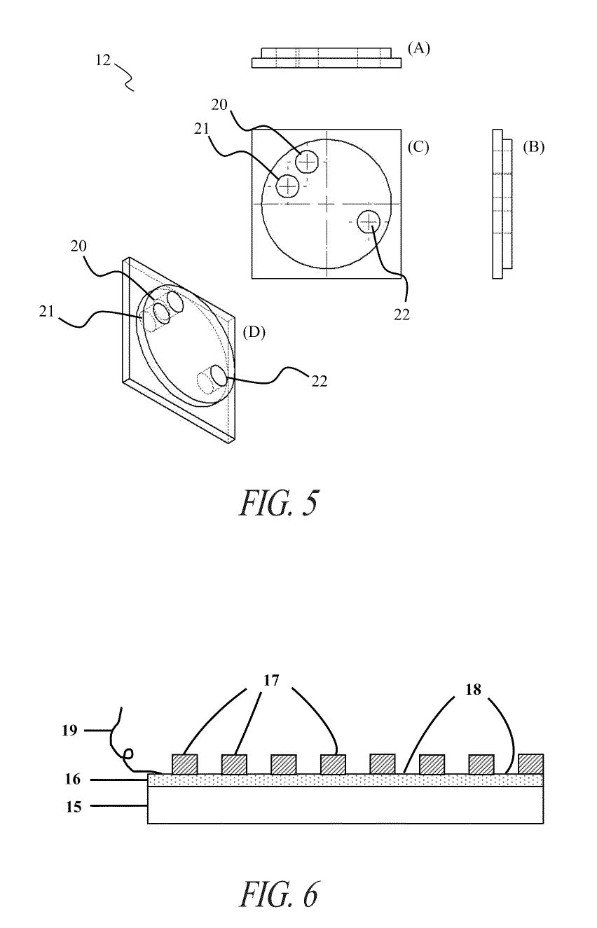

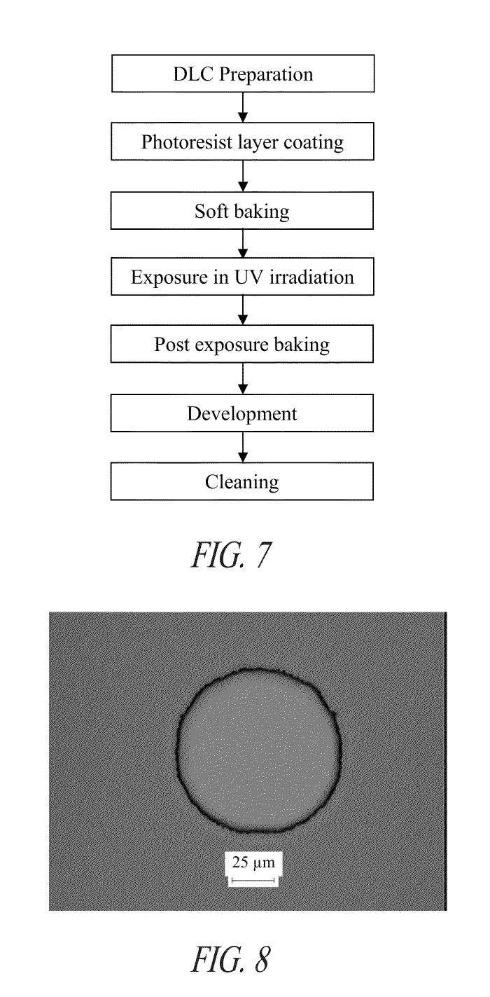

As illustrated in an exemplary embodiment in FIG. 6, microelectrodes 18 of the microelectrode array are defined by the openings formed in the overlying patterning layer 17. In other words, the doped carbon film 16 not covered by the patterning layer 17 forms the detecting portion of the doped carbon film which gets into contact with the aqueous solution to be tested for its content of trace metals. Due to the formation of a single doped carbon layer, the conduction of each defined microelectrode is connected to the conduction of all other microelectrodes in the microelectrode array. The finial current is the sum from all the individual microelectrodes in the array exposed to the solution, which is much stronger than that of a single microelectrode. A microelectrode array has higher current density and signal-to-noise ratio, lower background noise and capacitance current compared to a single microelectrode.

The patterning layer can be arranged on the doped carbon film to provide openings which are all identical in size and shape. In case the openings defining the microelectrodes comprise all the same size and shape the distance between any two neighboring microelectrodes (center to center) in the same direction thus defined is identical. Examples of such configurations are illustrated in FIG. 9. In another embodiment, the openings are different in shape or in size or in arrangement, or in shape and size and arrangement.

The area of a microelectrode in the array of microelectrodes or in other words the size of each of the openings in the patterning layer which define the microelectrodes can be between about 7 μm² and about 7855 μm².

A microelectrode in the microelectrode array can have a shape which is curved or composed of straight line segments. Examples of curved shapes include, but are not limited to circles, such as a disc shape, ellipses, oval and semicircle. Examples of straight line segments can include, but are not limited to polygon, triangle, trapezium, and quadrilateral, such as rectangle or rhomboid or trapezoid. In one embodiment, a microelectrode has a disc like shape. The diameter of such a disc like shaped microelectrode can be between about 3 μm and about 100 μm. Depending on the size, and shape, and arrangement of the individual microelectrodes the shortest distance between the neighboring microelectrodes (center to center) within the array varies depending on the ratio indicated above, i.e. 1:1.2 to 1:6.

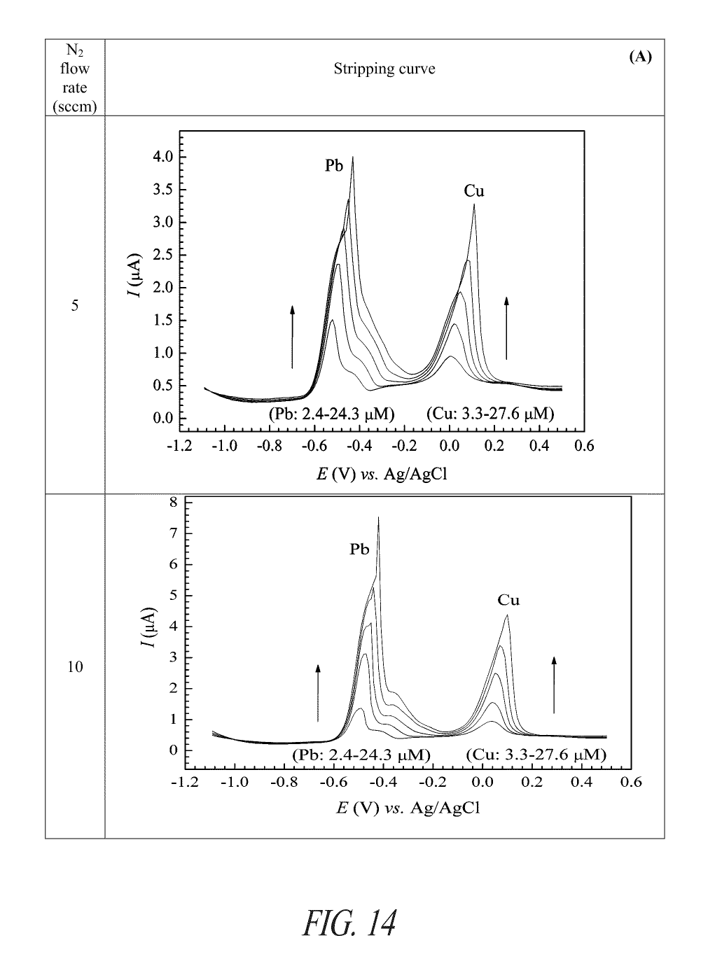

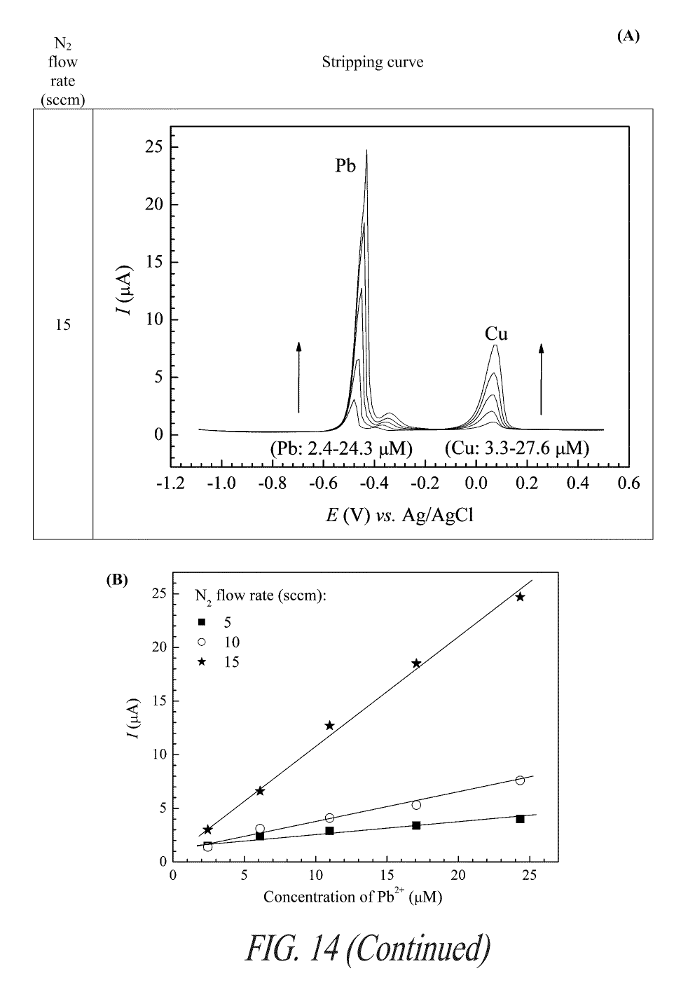

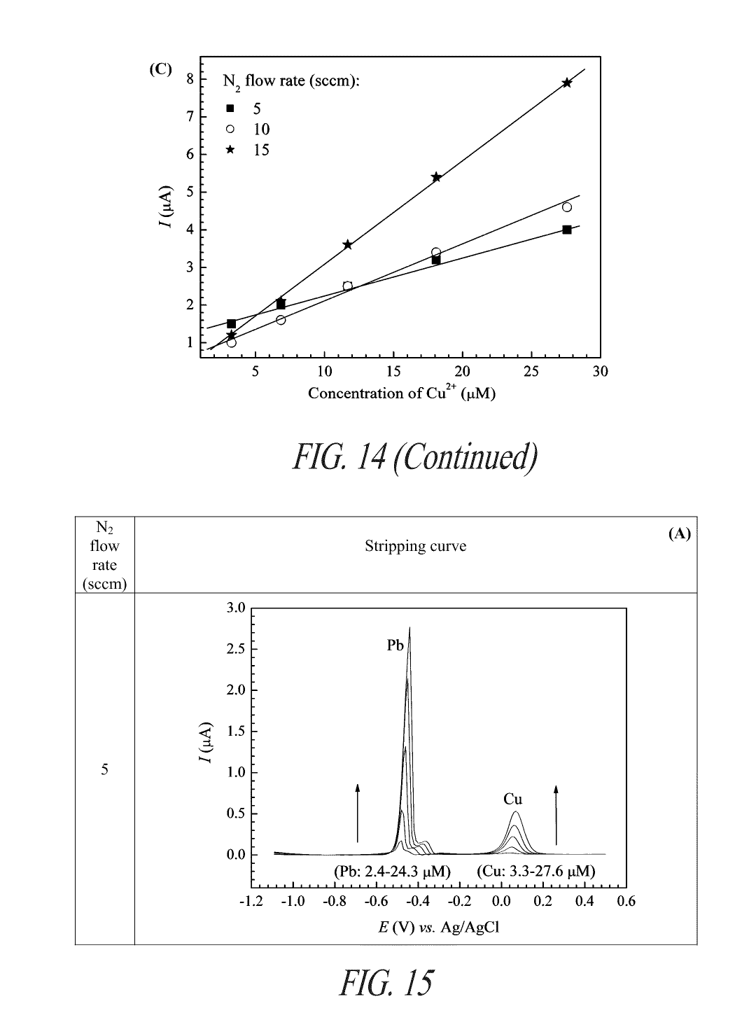

The mean surface roughness can increase with increased amount of dopant. In one embodiment, the mean surface roughness is below 5 nm or below 4 nm or below 3 nm or between about 0.5 nm and about 5 nm. A higher amount of dopant can increase the sensitivity of the microelectrode array as demonstrated by the results illustrated in FIG. 14.

The thickness of the patterning layer can affect the sensitivity of doped carbon film microelectrodes. A thicker patterning layer can make it harder for metal ions to deposit onto the surface of the DLC microelectrodes, thus reducing the sensitivity of the electrodes. Therefore, in one embodiment the thickness of the patterning layer is between about 5 μm and about 50 μm or between about 10 μm to about 25 μm.

The patterning layer can be made of a photoresist material. A “photoresist” is a light-sensitive material used in several industrial processes, such as photolithography and photoengraving to form a patterned coating on a surface. Photoresists can be classified into two groups: positive resists and negative resists. A positive resist is a type of photoresist in which the portion of the photoresist that is exposed to light becomes soluble to the photoresist developer. The portion of the photoresist that is unexposed remains insoluble to the photoresist developer. A negative resist is a type of photoresist in which the portion of the photoresist that is exposed to light becomes insoluble to the photoresist developer. The unexposed portion of the photoresist is dissolved by the photoresist developer. Both kinds of photoresist can be used herein.

The photoresist material can include a variety of photoresist chemicals suitable for lithographic applications. The photoresist material conventionally includes a matrix material or resin, a sensitizer or inhibitor, and a solvent. For example, the photoresist can include, but is not limited to polymethylmethacrylate (PMMA), polymethylglutarimide (PMGI), a mixture of diazonaphthoquinone (DNQ) and phenol formaldehyde resins (such as Novolac), and SU-8. These materials can be applied for example as a liquid and, generally, spin-coated to ensure uniformity of thickness.

SU-8 is a commonly used epoxy-based negative photoresist. It is a very viscous polymer that can be spun or spread over a thickness ranging from 0.1 μm up to 2 mm and still be processed with standard contact lithography. It can be used to pattern high aspect ratio (>20) structures. Its maximum absorption is for ultraviolet light with a wavelength of 365 nm. When exposed, SU-8's long molecular chains cross-link causing the solidification of the material. The main developer that can be used for SU-8 is PM acetate (2-methoxy-1-methyl ethyl acetate). Other developers can include, but are not limited to ethyl acetate, or diacetone alcohol.

The layer of doped carbon film can be deposited on a conducting substrate layer, wherein the conducting layer is arranged on the side of the layer of doped carbon film which is opposite the side of the patterning layer. The conducting substrate layer can be an extrinsic silicon wafer or a conducting glass or a conducting polymer.

Conducting glasses are glasses with electron conduction which differ from ordinary glasses since their conduction is several orders of magnitude higher and is executed by electrons. The electron conduction of oxide semiconductor glasses is due to the concentration of a large amount of oxides of elements of variable valence which have an unfilled d electron shell. They include Ti, V, Fe, Mn, Cu, Mo, W, and others. The presence of free sites in the d shell of the atoms of these elements allows them to be filled by electrons. Examples of such conducting glasses can include titanium semiconductor glasses, iron silicate, tungsten phosphate glasses, vanadium phosphate semiconductor glasses, and manganese silicate glasses. Other examples of conducting glasses can include low-melting conducting glasses and conducting pyrocerams. Low-melting conducting glasses (LCG) are based on lead borate and tellurite systems with a high concentration of iron, vanadium, tin, and cadmium oxides. Powders of these glasses crystallize during melting with separation of crystals of the conducting phase and can be used for creating conducting glass cements and glass composites. Examples of low-melting conducting glasses (LCG) can include, but are not limited to iron borate glass, bismuth glass, and pyroceramic LCG. Pyrocerams with electron conduction are heterogeneous monolithic formations consisting of a glass phase and a finely disperse conducting crystalline phase. Some pyrocerams are based on iron (ferrite) oxides, tin (cassiterite) oxides, and titanium oxides.

Conducting polymers are plastics that conduct electricity. Conducting polymers can include, but are not limited to polyaniline, polypyrrole, polythiophene, polyfuran, poly(p-phenylene-oxide), poly(p-phenylene-sulfide), substituted conducting polymers, poly(3,4-ethylenedioxythiophene) block PEG, and poly(3,4-ethylenedioxythiophene) (PEDOT), tetramethacrylate or mixtures thereof.

In addition, the microelectrode array can be connected to an electrical wire. The electrical wire can be arranged between the layer of doped carbon and the conducting substrate layer. Any known electrically conducting material can be used for the wire. An example of such a configuration is shown in FIG. 6 in which a wire 19 has been used. The wire can, for example, be made of aluminium, or copper or silver.

The microelectrode assay described herein can be used in an apparatus for detecting one or more metal ions in an aqueous solution. Detecting refers to the ability to determine the presence of a heavy metal in a solution being comprised in solution at a concentration of as low as 3×10⁻⁷ M.

Such an apparatus can comprise a measuring cell for an aqueous test sample and a working electrode comprising the microelectrode array described herein. The working electrode can be arranged to expose the microelectrode array to the aqueous test sample in the measuring cell. The measuring cell is adapted to take up a liquid sample suspected to comprise the heavy metals to be detected. The measuring cell can comprise a side wall with at least one opening through which the aqueous test sample can contact the microelectrode array of the working electrode. The opening which exposes the underlying microelectrode array can have an area of between about 7 mm² and about 78 mm².

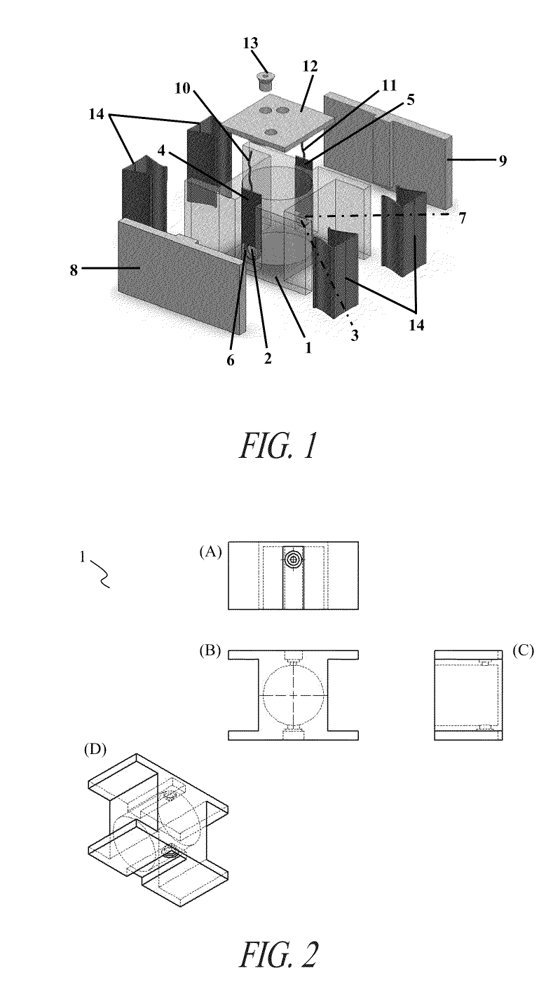

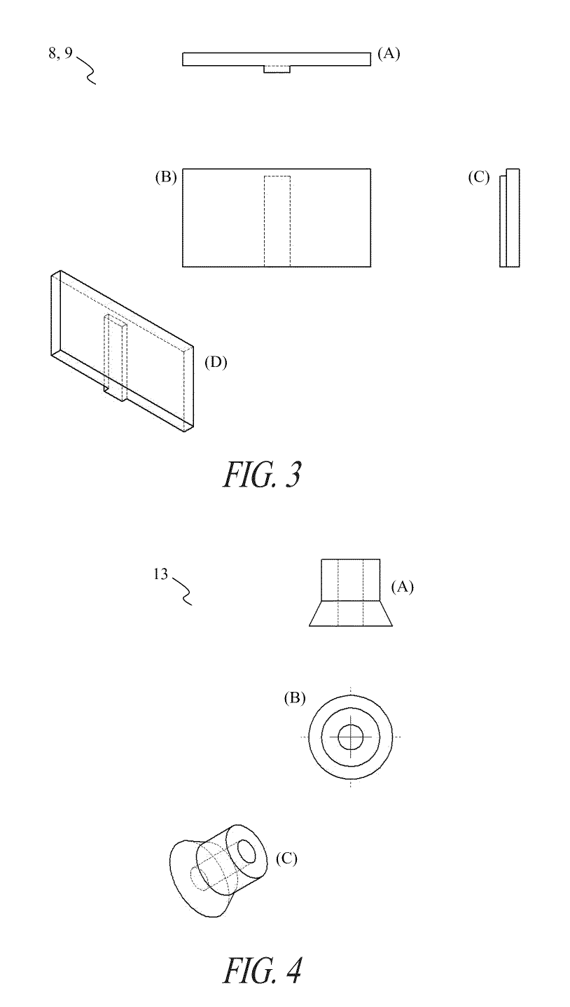

An example of such an apparatus is illustrated in FIG. 1. The apparatus or electrochemical cell can be made entirely or partly of an inert material, such as polytetrafluoroethylene (Teflon®). At least the portion of the apparatus exposed to the liquid test sample is made of an inert material. The apparatus in FIG. 1 comprises a container 1 which can be made of an inert material or having sidewalls made of an inert material. The volume of such a container 1 can be between about 4 cm³ to 100 cm³. The container of the apparatus can provide one or more, such as two openings or holes (2 and 3), having a varying opening area of about 7 mm² to about 78 mm² to expose the working electrode to the liquid test sample. In case more than one opening is comprised in the wall of the container 1, the openings can have the same or different sizes. Different sizes of the openings allow two different sizes of working electrodes in operation at the same time.

The two working electrodes 4 and 5 comprising the microelectrode arrays are close to the holes on both sides of the container. O-rings 6 and 7 can be used to seal the working electrodes and avoid the leakage of liquid in the cell. Clamped plates 8 and 9 can be pressed to firmly hold the two working electrodes 4 and 5 by means of four fasteners 14 that also consolidate the container 1 and clamped plates 8 and 9. Wires 10 and 11 adhered to the working electrode 4 and 5 surfaces can be connected to a control unit (not shown). Thus, the apparatus can comprise a control unit for measuring and analyzing the electrical signals obtained from the electrochemical cell. A cap 12 can be used to hold reference and auxiliary electrodes. A liquid test sample can be injected into the container 1 through a hole in the cap 12. A holder 13 can be used to fix a tube to inject gas if necessary.

In another aspect the present invention is directed to a water treatment plant comprising an apparatus as described herein. The apparatus can be used to take periodic samples from the treated water to determine the amount of heavy metals if present. The liquid samples can be taken manually or automatically. The apparatus described herein can be used as stand alone, portable unit or can be implemented into the water treatment system of such a plant to automatically divert liquid test samples from the main stream of treated or to be treated water for determining the presence or absence and the exact amount of heavy metal ions comprised therein.

In another aspect the present invention is directed to a method of determining the presence or absence of one or more heavy metals in a liquid test sample or to determine the concentration of one or more metals in a liquid test sample. The method can comprise taking a liquid test sample and filling it in an apparatus described herein followed by determining the electrical signal indicating the presence or absence or the concentration of the one or more metals measured in the test sample. The test sample can be obtained from a water treatment plant or it can be a biofluid, such as blood or urine or sweat or any other biofluid obtained from an animal body, such as a human, which is suspected to comprise heavy metals. The microelectrode array can also be coupled to or implemented in a biosensor system.

In another aspect the present invention is directed to a method of manufacturing a microelectrode array of the present invention. The method can comprise coating a patterning layer on a doped carbon film. It can further comprise baking the patterning layer to densify the patterning layer and covering it with a masking layer and exposing the baked and masked patterning layer to UV radiation. It can further comprise performing a post-exposure baking and performing a development process to remove portions of the baked and masked patterning layer thereby exposing areas of the doped carbon film which areas form microelectrodes of the microelectrode array. FIG. 7 shows a flow chart of a specific example of this method in which the patterning layer is a photoresist layer and the layer of doped carbon is a layer of doped diamond-like carbon (DLC).

In one embodiment the patterning layer is a positive photoresist wherein exposing the baked and masked patterning layer to UV radiation comprises removing portions of the patterning layer exposed to UV radiation. In another embodiment the patterning layer is a negative photoresist wherein exposing the baked and masked patterning layer to UV radiation comprises removing portions of the patterning layer unexposed to UV radiation.

As already described, the doped carbon film can be manufactured by methods known in the art, such as filtered cathodic vacuum arc or magnetron sputtering methods, such as DC magnetron sputtering. Baking the patterning layer and/or post-exposure baking can be carried out on a hot plate. Use of a leveled hot plate for baking can be more efficient and controllable, and does not trap the solvent compared to conventional oven baking process.

Furthermore, baking the patterning layer and/or post-exposure baking can be carried out using two-step contact heating or slow-ramp heating for each baking, i.e. baking of patterning layer and post-exposure baking of patterning layer. Those methods can be used to minimize the stresses in the photoresist layers during baking to avoid the distortion and cracking of the patterning layer.

Two-step contact heating comprises a first baking and a second baking. The temperature used for the first baking is lower than the temperature used for the second baking. The first baking (soft baking) can be carried out at a temperature between about 55 and about 70° C. In one example a temperature of about 65° C. has been used. For the second baking a temperature between about 85 and about 100° C. can be employed. In one example the temperature is about 95° C.

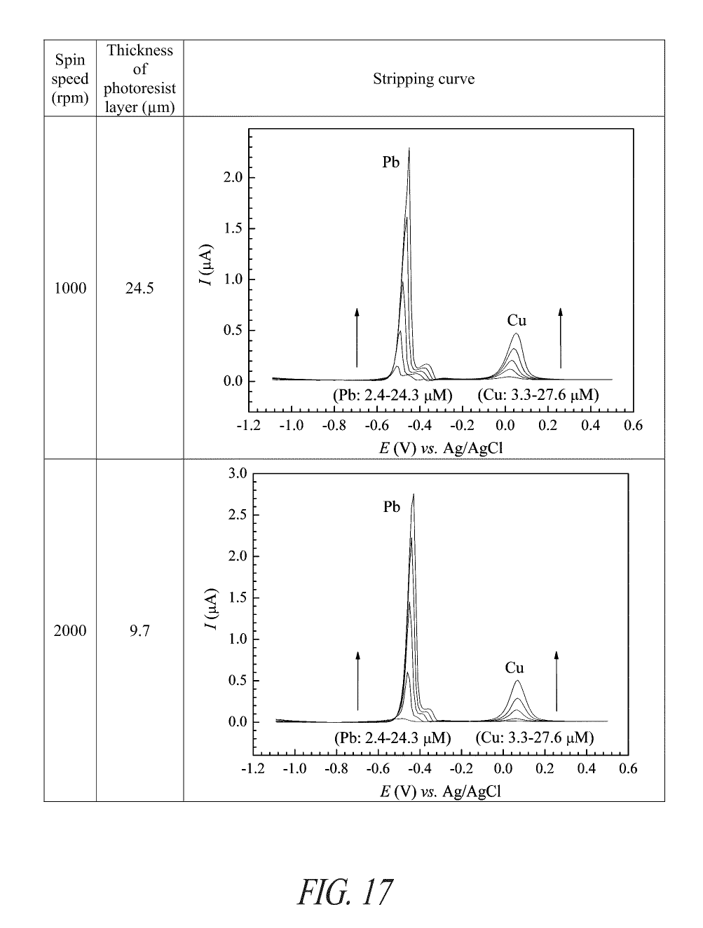

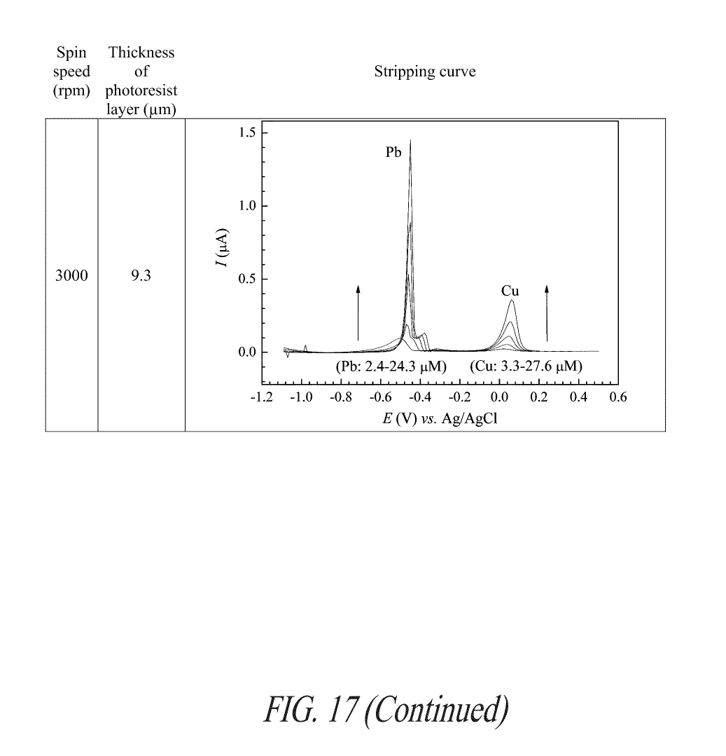

The patterning layer can be coated on the layer of doped carbon by any method known in the art. For example, the patterning layer can be formed via electrospinning. In one embodiment, the patterning layer is coated onto the layer of doped carbon in two sequences. Firstly, the spinning speed for electrospinning of the patterning layer increases from 0 to about 500 rpm in increments of 80 rpm/s to 120 rpm/s or about 100 rpm/s. Subsequently, the spinning speed is increased to about 1000 rpm/s or about 2500 rpm/s or about 3000 rpm/s in increments of about 230 rpm/s to about 270 rpm/s or about 250 rpm/s. After the increase the spinning speed can be kept for a certain time, such as about 30 seconds to obtain desired patterning layer thickness. By increasing the final spin speed the thickness of the patterning layer can be decreased. The thickness can for example be decreased from about 24 μm to about 10 μm. As higher the final spin speed as thinner the thickness of the patterning layer as illustrated by FIG. 17.

In one embodiment, the method can comprise (a) depositing a doped carbon film, such as a doped diamond-like carbon film on a conducting substrate layer by filtered cathodic vacuum arc or magnetron sputtering; (b) cleaning the conducting substrate layer/doped carbon layer with dilute acid followed by de-ionized water; (c) coating a patterning layer, such as a SU-8 photoresist layer, on the surface of the doped carbon film; (d) softly baking the patterning layer on a level hot plate to evaporate the solvent used for deposition of the patterning layer and densify the patterning layer; (e) exposing the former sandwich structure of conducting substrate layer/doped carbon layer/patterning layer covered with an additional patterned mask (masking layer) on it to a UV irradiation, such as UV irradiation at 350 to 400 nm in wavelength; (f) performing a post exposure baking of the selectively cross-linked portions of the patterning layer on a hot plate; (g) removing the exposed patterning layer using a developer; (h) rinsing the resulted conducting substrate layer/doped carbon layer/patterning layer with de-ionized water or isopropyl alcohol followed by drying with a gentle stream of air or nitrogen to remove the water or isopropyl alcohol on it. The development time using the developer can be between about 2 minutes and about 4 minutes. Further exemplary embodiments are described in the experimental section.

The inventions illustratively described herein may suitably be practiced in the absence of any element or elements, limitation or limitations, not specifically disclosed herein. Thus, for example, the terms “comprising”, “including”, “containing”, etc. shall be read expansively and without limitation. Additionally, the terms and expressions employed herein have been used as terms of description and not of limitation, and there is no intention in the use of such terms and expressions of excluding any equivalents of the features shown and described or portions thereof, but it is recognized that various modifications are possible within the scope of the invention claimed. Thus, it should be understood that although the present invention has been specifically disclosed by preferred embodiments and optional features, modification and variation of the inventions embodied therein herein disclosed may be resorted to by those skilled in the art, and that such modifications and variations are considered to be within the scope of this invention.

The invention has been described broadly and generically herein. Each of the narrower species and subgeneric groupings falling within the generic disclosure also form part of the invention. This includes the generic description of the invention with a proviso or negative limitation removing any subject matter from the genus, regardless of whether or not the excised material is specifically recited herein.

Other embodiments are within the following claims and non-limiting examples. In addition, where features or aspects of the invention are described in terms of Markush groups, those skilled in the art will recognize that the invention is also thereby described in terms of any individual member or subgroup of members of the Markush group.

### Experimental Section

### Manufacturing Microelectrode Arrays

The microelectrode arrays comprise diamond like carbon (DLC) films doped with finely-dispersed nitrogen, or platinum/ruthenium, or aluminium or nickel, which were deposited on various substrates, such as conductive silicon wafer, glass or resin by filtered cathodic vacuum arc or magnetron sputtering methods. The concentrations of C, N, Pt/Ru, Al or Ni in the DLC films ranged about 70-99.5, 0.5-3, 1-10, 1-10 or 1-10 at. %, respectively. The thickness of the DLC films was less than 1 μm, the surface roughness of the films lower than 5 nm, and the electrical resistivity of the films smaller than 10⁴ Ohm*cm. A layer of SU-8 photoresist was then coated on the DLC surfaces firstly with an increasing spin speed from 0 to 500 rpm with an increment of 100 rpm/s and then an increasing spin speed from 500 to a final spin speed of 1000, 2000 or 3000 rpm with an increment of about 250 rpm/s and held for 30 s at the respective final spin speeds of 1000, 2000 or 3000 rpm. The thickness of the SU-8 photoresist layer varied from about 5 μm to about 50 μm. After soft baking at 65° C. for 2 min and 95° C. for 5 min, sequentially a sandwich structure of Si/DLC/SU-8 covered with a patterned mask on it was exposed to 350 to 400 nm UV irradiation for about 17 seconds to about 22 seconds. For all the methods described herein, the UV irradiation step can be from between about 17 and about 22 seconds. For all the methods described herein, the exposure energy can be between about 160 mJ/cm² and about 205 mJ/cm². A post exposure baking to the selectively cross-linked exposed portions of the photoresist was carried out through a two-step contact hot plate process, namely one minute at 65° C. followed by one to two minutes at 95° C. A development process was then performed followed by final cleaning using de-ionized water. An exemplary flowchart of preparing DLC-based microelectrodes by photolithography is shown in FIG. 7. The electrodes developed were either single electrodes with a diameter of about 100 μm to about 10 mm or arrays of microelectrodes wherein each disc-shaped microelectrode has a diameter of between about 3 μm and about 100 μm. The shortest distance between the neighboring disc-shaped microelectrodes (center to center) is between about 3.6 μm and about 600 μm.

### Manufacturing of Doped Carbon Thin Films Via Cathodic Vacuum Arc Method

Diamond-like carbon thin films with nitrogen doping were synthesized by filtered cathodic vacuum arc with the following steps: (a) rinsing the bare substrates with acetone and de-ionized water in an ultrasonic bath for 15 to 30 min followed by drying with compressed nitrogen gas before they were put into the vacuum chamber; (b) etching the bare substrates by energetic Ar⁺ ions produced by Kaufman gun for 3 min at a pressure of about 2×10⁻⁶ Torr (2.67×10⁻⁴ Pa); (c) introducing 1-60 sccm (1.67×10⁻⁸ to 10⁻⁶ m³/s) high purity nitrogen gas (99.999%) into the vacuum chamber until a dynamically balanced pressure of 10⁻⁴-10⁻⁶ Torr (1.33×10⁻² to 1.33×10⁻⁴ Pa) was obtained; (d) setting an arc current of 30-90 A, a magnetic field intensity of the filtered duct of 20-60 mT, a pulse negative substrate bias from 0 to 2000 V and a pulse frequency of 1000-2500 Hz; (e) igniting the carbon arc by the striker and ionized or energized carbon and nitrogen were deposited on the substrate surfaces.

### Manufacturing of Doped Carbon Thin Films Via DC Magnetron Sputtering

Diamond-like carbon thin films with nitrogen doping were synthesized by DC magnetron sputtering with the following steps: (a) rinsing the bare substrates with acetone and de-ionized water in an ultrasonic bath for 15 to 30 min followed by drying with a hair dryer before they were put into the vacuum chamber; (b) etching the bare substrates by argon plasma at a radio frequency of 13.56 MHz and a power of 250 W for 20 min to remove undesirable surface oxide layers and any other impurities at a vacuum level of about 3×10⁻³ Torr (0.4 Pa); (c) introducing 1-60 sccm (1.67×10⁻⁸ to 10⁻⁶ m³/s) high purity nitrogen gas into the vacuum chamber through a mass flow controller until a dynamically balanced pressure of about 10⁻³ Torr (0.13 Pa) was obtained; (d) depositing the films on substrates with a DC power of 650-850 W applied to a pure graphite target (99.995%) of 4 inch (10.2 cm) in diameter at room temperature.

Diamond-like carbon thin films (DLC) doped with platinum/ruthenium, aluminium or nickel were synthesized by DC magnetron co-sputtering with the following steps: (a) rinsing the substrates with acetone, ethanol and de-ionized water in an ultrasonic bath for 15-30 min followed by drying with a hair dryer before they were put into the vacuum chamber; (b) etching the bare substrates by argon plasma at a radio frequency of 13.56 MHz and a power of 250 W for 20 min to remove undesirable surface oxide layers and any other impurities at a vacuum level of about 3×10⁻³ Torr (0.4 Pa); (c) a DC sputtering power of 650 W was applied to a pure graphite target (99.995%) and a RF bias voltage of −50 V applied to the substrates. A DC sputtering power applied to the platinum/ruthenium, aluminium or nickel target (99.999%) at the same time was from 10 to 80 W; (d) depositing doped DLC films on the substrates by co-sputtering the graphite and metal targets in an argon gas environment (99.99%) at room temperature. An Ar flow rate of about 50 sccm (8.35×10⁻⁷ m³/s) was controlled by a mass flow controller and the deposition pressure in the deposition chamber was about 3.5×10⁻³ Torr (0.47 Pa).

### Manufacturing an Apparatus Comprising a Microelectrode Array

In one example, an apparatus comprises a measuring cell of 4 to 100 cm³ in volume with two openings having a varying opening area of about 7 mm² to about 78 mm² to expose the microelectrode array comprised in the working electrode to the aqueous test solution. In the measuring cell, two metal wires are adhered to the surfaces or backsides of the two working electrodes. Two clamped plates are used to fix the working electrodes and two O-rings to seal the working electrodes to avoid the leakage of the aqueous test solution in the cell. Further comprised is a Teflon® cap to connect a commercial available reference electrode of Ag/AgCl (with saturated KCl solution in it) and an auxiliary electrode of platinum and inject aqueous test solution. Also comprised is a Teflon® holder to connect a tube to inject gas into the measuring cell when necessary, and four metal snap fasteners to consolidate the container and clamped plates. The cell is fabricated by several machining processes such as drilling, turning and milling. A rectangular Teflon® block is used to make the cell. The sink portion of the cell is created by first drilling a hole on the top surface of the Teflon® block, and then turning to achieve desired precision and surface finish. The rest profile of the cell is achieved by milling with the holes for electrodes being drilled.

### Effect of Surface Roughness of Doped Diamond Like Carbon Films

The surface roughness of the doped DLC films increased with increased nitrogen content via increased sp² sites and nitrogen aggregates in the films. A relatively higher surface roughness of a DLC film having a relatively higher nitrogen content was also expected to be able to enhance the sensitivity of the film electrode since stripping peak current was directly proportional to the exposed surface area of the film electrode to analytes.

The measurement results of different nitrogen-doped DLC thin film electrodes (apparent area≈7 mm²) in 0.1 M HAc−NaAc solutions (pH 6.0) including Pb and Cu ions of various concentrations are displayed in FIG. 14 A. The calibration curves show that for example a nitrogen-doped DLC film electrode prepared with 15 sccm (2.51×10⁻⁷ m³/s) N₂ has the highest sensitivity due to its highest N content and surface roughness. Undesirable surface roughness is about submicron level which can abruptly affect the performance of electrodes in terms of data accuracy. For DLC films, the surface roughness of the films is up to several nanometers which are rather low. At such a low surface roughness level, a relatively higher surface roughness can enhance the sensitivity of the films by increased surface areas on which more metal atoms can be deposited. The mean surface roughness of DLC films is between about 0.3 nm and about 5 nm.

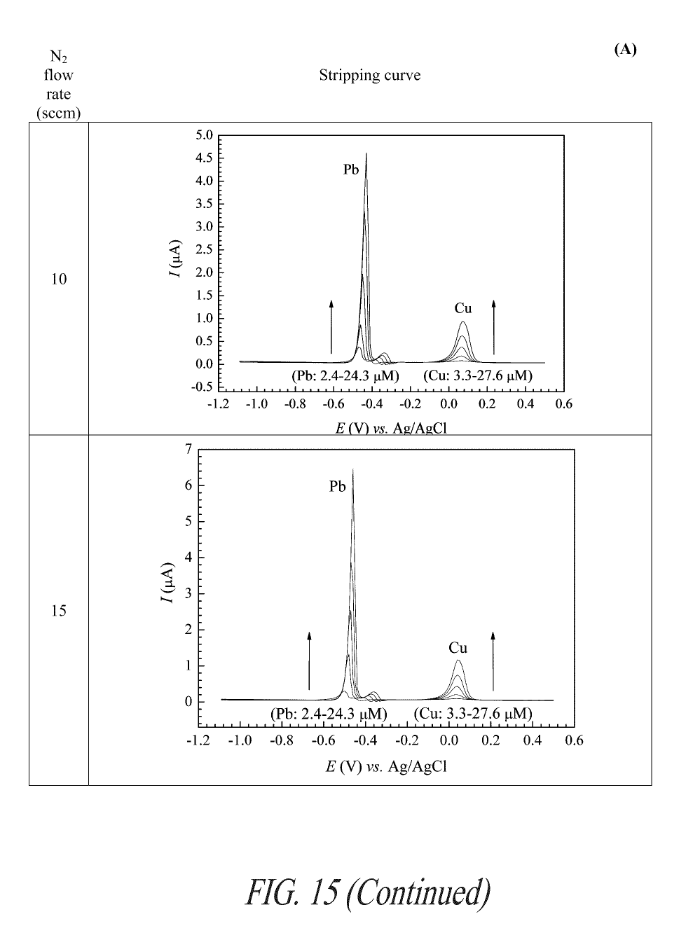

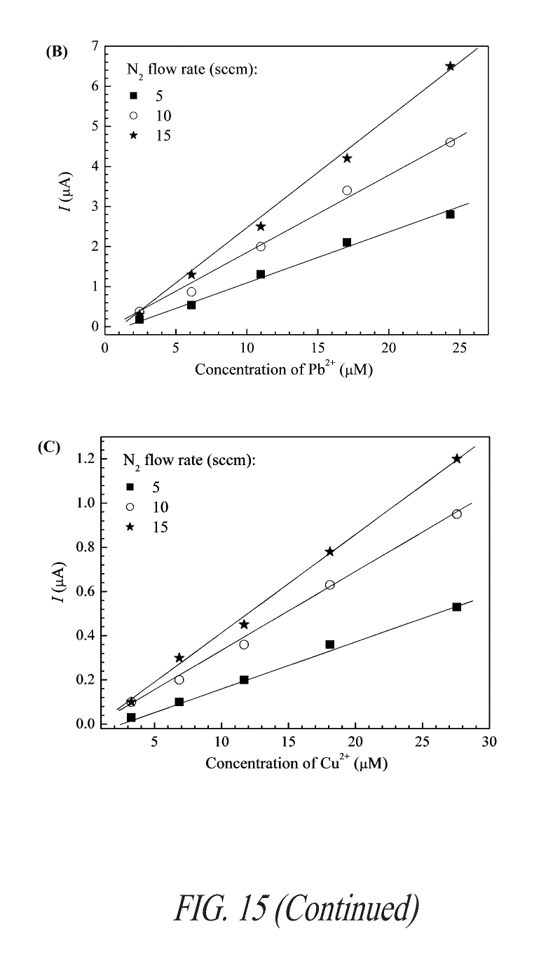

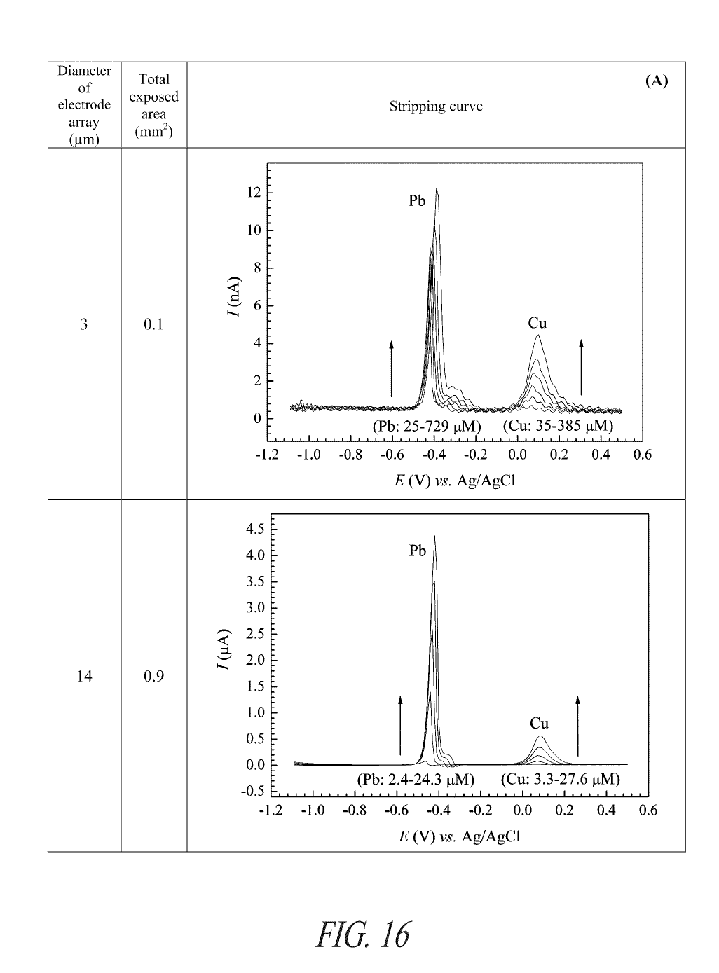

A similar conclusion can be obtained by analyzing the results of different nitrogen-doped DLC microelectrode arrays with a diameter of 100 μm for the microelectrodes and the shortest spacing between the neighboring microelectrodes (center to center) of 250 μm (total exposed DLC area: about 0.7 mm²) in the 0.1 M HAc−NaAc solutions (pH 6) including Pb and Cu ions. A layer of SU-8 photoresist was coated on the DLC film surfaces firstly at an increasing spin speed from 0 to 500 rpm with an increment of 100 rpm/s and then an increasing spin speed from 500 to 2500 rpm with an increment of 250 rpm/s followed by holding the spinning at 2500 rpm for 30 s. The results displayed in FIG. 15 A indicate that the nitrogen-doped DLC microelectrode arrays prepared with 15 sccm (2.51×10⁻⁷ m³/s) N₂ have the highest sensitivity due to their highest N content and surface roughness.

### Effect of Diameter of Microelectrodes in Microelectrode Array

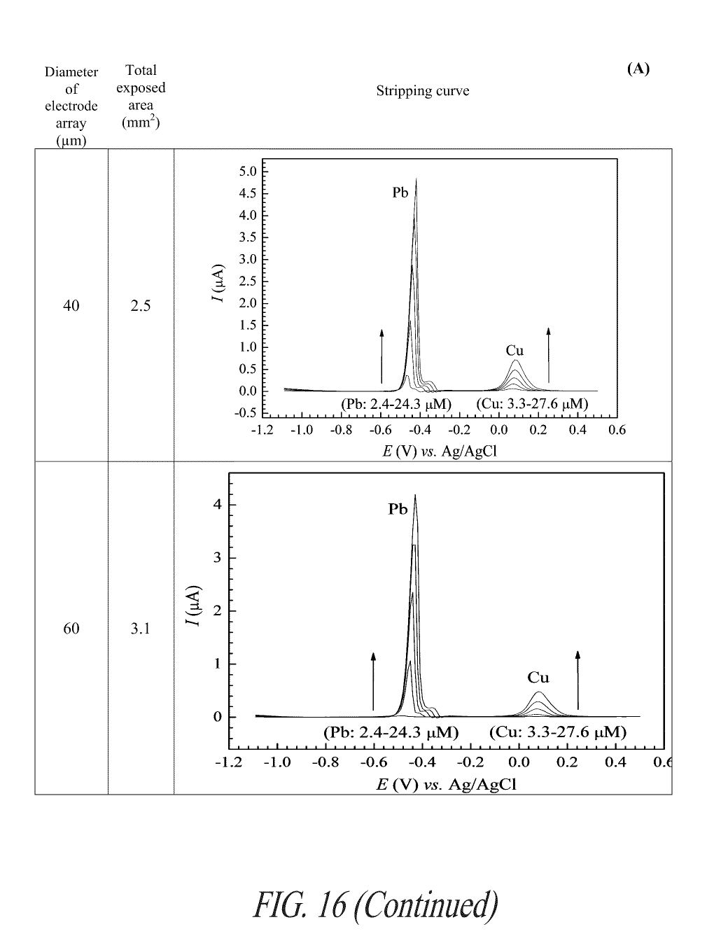

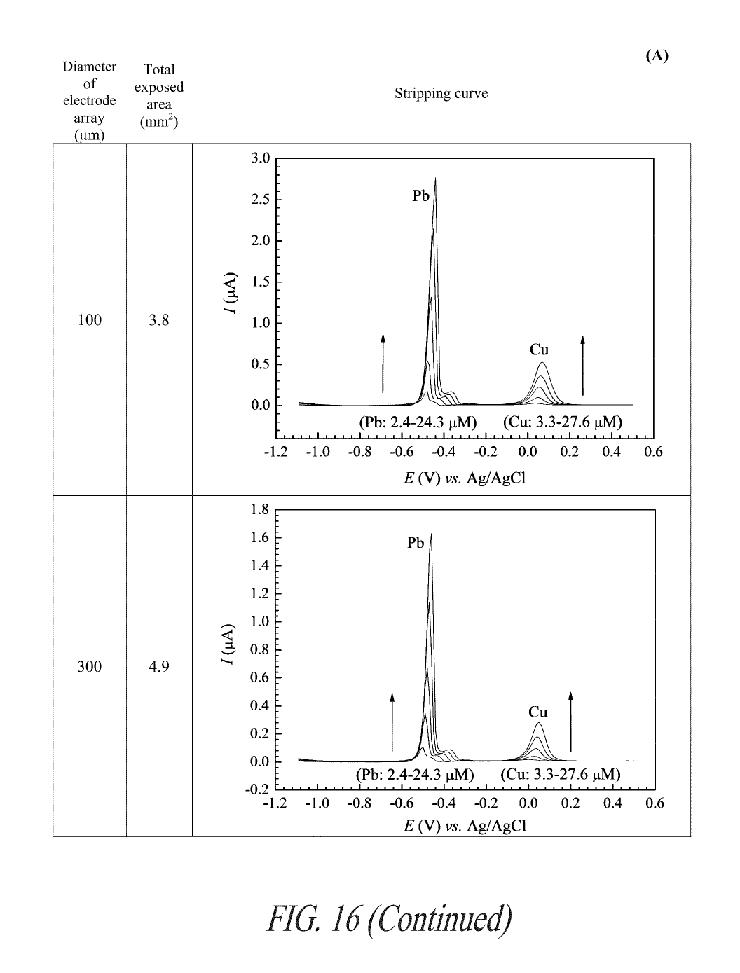

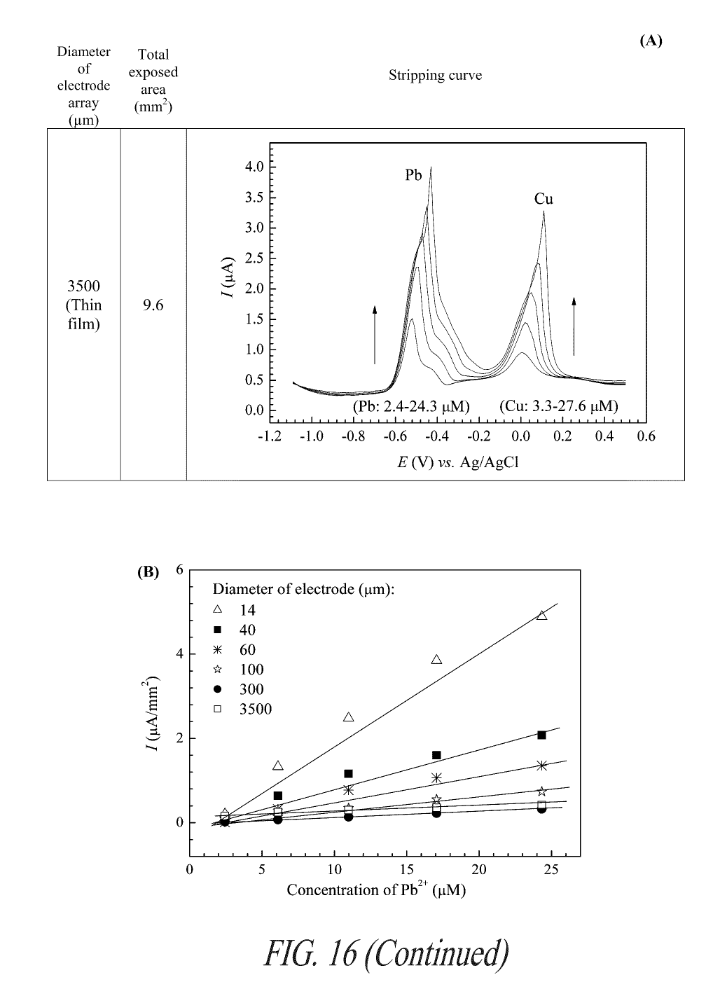

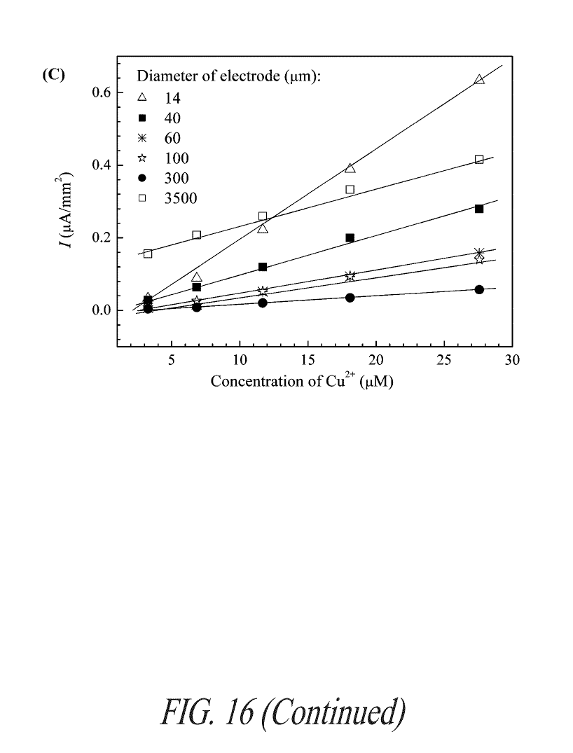

The size of DLC microelectrodes in a microelectrode array or the real exposed area of the microelectrodes affects the performance of nitrogen-doped DLC microelectrodes. The following FIG. 16 illustrates the electrochemical results of the nitrogen-doped DLC microelectrodes of different diameters in the 0.1 M HAc−NaAc solutions (pH 6) containing Pb and Cu ions. The layer of SU-8 photoresist was coated on the DLC film surfaces firstly at an increasing spin speed from 0 to 500 rpm with an increment of 100 rpm/s and then an increasing spin speed from 500 to 2500 rpm with an increment of 250 rpm/s followed by holding the spinning at 2500 rpm for 30 s. It can be seen that the response currents first increase and then decrease with the increasing diameter of the microelectrodes. The total area exposed to the solution also shows a similar trend. The maximum sensitivity (charges consumed per square millimeter in metal oxidation in positive scan) is obtained with the nitrogen doped DLC microelectrodes having a diameter of 14 μm. However, when the diameter of microelectrodes decreases to 3 μm, the response current is very low (nA level).

### Effect of Thickness of Patterning Layer

The thickness of patterning layer, such as a photoresist layer, can affect the sensitivity of doped DLC microelectrodes. The thickness of patterning layer can be controlled by changing the spin speed when the patterning layer is coated on a DLC film surface. By increasing the final spin speed from 1000 to 3000 rpm, the thickness of the patterning layer decreases from about 24 μm to about 10 μm. A thicker layer makes it harder for metal ions to deposit onto the surface of the DLC microelectrodes, thus reducing the sensitivity of the electrodes. Therefore, a high spin speed is preferred for coating photoresist layers to increase the sensitivity of DLC microelectrodes. For example, FIG. 17 illustrates stripping current response of nitrogen-doped DLC microelectrode arrays formed with different thicknesses of photoresist layers in 0.1 M NaAc+HAc solutions (pH 6.0) containing Pb and Cu ions of various concentrations.

### Baking the Patterning Layers to Densify the Patterning Layers (Soft Baking)

After the patterning layers were coated on the doped DLC films, they were baked at 65° C. for 2 min and subsequently at 95° C. for 5 min, for example, to evaporate the solvent and densify the photoresist layers. For example, SU-8 photoresist which can be used as patterning layer was normally baked on a leveled hot plate that was more efficient and controllable, and did not trap the solvent compared to conventional oven baking process.

Table 1 summarizes the baking parameters used in one embodiment. The baking time was optimized since the solvent evaporation rate was influenced by heat transfer and ventilation. For the optimum results, ramp heating was recommended as a lower initial baking temperature, which allowed the solvent to evaporate out of the photoresist layers at a controlled rate and resulted in a better quality of the microelectrodes.

TABLE 1
Exemplary soft baking parameters

| Thickness of | Step 1 | | Step 2 | |
|---|---|---|---|---|
| photoresist layer | Temperature | Duration | Temperature | Duration |
| (μm) | (° C.) | (min) | (° C.) | (min) |
| 10 | 65 | 2 | 95 | 5 |
| 30 | | 3 | | 7 |
| 50 | | 5 | | 15 |

### Post Exposure Baking

The post exposure baking (PEB) of the patterning layer was performed to selectively cross-link the exposed portions of the photoresist layers by means of either a hot plate or a convection oven. An optimum cross-linking density was obtained through careful control of the PEB process conditions. The baking parameters referred to in Table 2 were based on the results obtained with a contact hot plate. The patterning layer, in this embodiment a SU-8 photoresist layer, was readily cross-linked and could lead to highly strained layers. To minimize the stresses in the photoresist layers in order to avoid the distortion and cracking of the photoresist layers, slow ramp heating or two-step contact heating was used as shown in Table 2. In one embodiment rapid cooling after PEB was avoided.

TABLE 2
Exemplary post exposure baking parameters

| | Thickness | Step 1 | | Step 2 | |
|---|---|---|---|---|---|
| Photoresist | (μm) | ° C. | (min) | ° C. | (min) |
| SU-8 | 10 | 65 | 1 | 95 | 2 |
| | 30 | | 1 | | 3 |
| | 50 | | 1 | | 4 |

1. A microelectrode array for detecting heavy metals in an aqueous solution, wherein the microelectrode array comprises:
a layer of a doped carbon film; and
a patterning layer arranged on the doped carbon thin film for defining multiple microelectrodes in the doped carbon thin film to form the microelectrode array;
wherein the size, and shape, and arrangement of each of the multiple microelectrodes are defined by the size, and shape, and arrangement of each of the openings in the patterning layer which expose the underlying doped carbon thin film; and
wherein the ratio of the maximal width of a microelectrode relative to the shortest distance between the neighboring microelectrodes (center to center) in the microelectrode array is between about 1:1.2 and about 1:6.

2. The microelectrode array of claim 1, wherein the thickness of the doped carbon films is <1 μm.

3. The microelectrode array of claim 1, wherein the surface roughness of the doped carbon film is less than 5 nm.

4. The microelectrode array of claim 1, wherein the electrical resistivity of the doped carbon film is <10⁴ Ohm*cm.

5. The microelectrode array of claim 1, wherein the thickness of the patterning layer is between about 5 to 50 μm.

6. The microelectrode array of claim 1, wherein each of the microelectrodes has a shape which is curved or composed of straight line segments.

7. The microelectrode array of claim 6, wherein the curved shape is a circle or ellipse.

8. The microelectrode array of claim 1, wherein each of the multiple microelectrodes has an area of between about 7 μm² and about 7850 μm².

9. The microelectrode array of claim 1, wherein each of the multiple microelectrodes has a circular shape.

10. The microelectrode array of claim 9, wherein the diameter of each of the multiple microelectrodes is between about 3 μm and about 100 μm.

11. The microelectrode array of claim 1, wherein the doped carbon film is doped with at least one dopant selected from the group consisting of nitrogen, a mixture of platinum and ruthenium, aluminium, nickel and mixtures of the aforementioned dopants.

12. The microelectrode array of claim 11, wherein the dopant is nitrogen.

13. The microelectrode array of claim 1, wherein the doped carbon film comprises a dopant in an amount of between about 0.5 at. % and about 10 at. %.

14. The microelectrode array of claim 1, wherein the density of the microelectrode array is between about 200 microelectrodes/cm² and about 4.9×10⁶ microelectrodes/cm².

15. The microelectrode array of claim 1, wherein the layer of doped carbon film is arranged on a conducting layer, wherein the conducting layer is arranged on the side of the layer of doped carbon film which is opposite the side of the patterning layer.

16. The microelectrode array of claim 15, wherein the conducting layer is a conducting silicon wafer, or a conducting glass or a conducting polymer.

17. The microelectrode array of claim 1, wherein the patterning layer is made of a photoresist material.

18. The microelectrode array of claim 17, wherein the photoresist material is a positive resist or negative resist.

19. The microelectrode array of claim 18, wherein the photoresist is selected from the group consisting of polymethylmethacrylate, polymethylglutarimide, phenol formaldehyde resin and SU-8.

20. An apparatus for detecting heavy metals in a liquid test sample, wherein the apparatus comprises:
a measuring cell for a liquid test sample;
a working electrode comprising the microelectrode array referred to in claim 1,
wherein the working electrode is arranged to expose the microelectrode array to the liquid test sample in the measuring cell.

21. The apparatus of claim 20, wherein the measuring cell comprises a side wall with at least one opening through which the liquid test sample can contact the microelectrode array of the working electrode.

22. The apparatus of claim 21, wherein the area of the at least one opening is from about 7 mm² to about 78 mm².

23. The apparatus of claim 20, wherein the portion of the measuring cell exposed to the liquid test sample is made of an inert material.

24. The apparatus of claim 23, wherein the inert material is polytetrafluoroethylene.

25. A water treatment plant comprising an apparatus according to claim 20.

26. A method of manufacturing a microelectrode array as referred to in claim 1, wherein the method comprises:
coating a patterning layer on a doped carbon film;
baking the patterning layer to densify the patterning layer and covering it with a masking layer to obtain a baked and masked patterning layer;
exposing the baked and masked patterning layer to UV radiation;
performing a post-exposure baking; and
performing a development process to remove portions of the baked and masked patterning layer thereby exposing areas of the doped carbon film which areas form microelectrodes of the microelectrode array.

27. The method of claim 26, wherein baking the patterning layer and/or post-exposure baking are carried out on a hot plate.

28. The method of claim 26, wherein baking the patterning layer and/or post-exposure baking is carried out using ramp heating.

29. The method of claim 26, wherein baking the patterning layer and/or post-exposure baking comprises a first baking and a second baking, wherein the temperature for the first baking is lower than that for the second baking.

30. The method of claim 29, wherein the first baking is carried out at a temperature between about 55° C. and about 70° C.

31. The method of claim 29, wherein the second baking is carried out at a temperature between about 85° C. and about 100° C.

32. The method of claim 26, wherein the patterning layer is a positive photoresist and wherein exposing the baked and masked patterning layer to UV radiation comprises removing portions of the patterning layer exposed to UV radiation.

33. The method of claim 26, wherein the patterning layer is a negative photoresist and wherein exposing the baked and masked patterning layer to UV radiation comprises removing portions of the patterning layer unexposed to UV radiation.
